(19) United States
(12) Patent Application Publication
(10) Pub. No.: US 2026/0120764 A1
(43) Pub. Date: Apr. 30, 2026

(54) HYBRID COMPUTING-IN-MEMORY (CIM) DEVICE AND A METHOD FOR SENSING MULTI-LEVEL DATA BIT WITH THE SAME

(71) Applicant: The Hong Kong University of Science and Technology, Hong Kong (CN)

(72) Inventors: Xiaomeng WANG, Hong Kong (CN); Jingyu HE, Hong Kong (CN); Chi Ying TSUI, Hong Kong (CN); Kwang Ting CHENG, Hong Kong (CN); Kunming SHAO, Hong Kong (CN); Jiakun ZHENG, Hong Kong (CN); Fengshi TIAN, Hong Kong (CN)

(21) Appl. No.: 19/363,696

(22) Filed: Oct. 21, 2025

Related U.S. Application Data
(60) Provisional application No. 63/711,711, filed on Oct. 25, 2024.

(51) Int. Cl. G11C 13/00; G11C 11/418

(52) U.S. Cl. CPC G11C 13/004; G11C 11/418; G11C 2013/0042

(57) ABSTRACT

The present invention provides A hybrid computing-in-memory (CIM) device, comprising: an array of resistive random-access memory (ReRAM) cells, each ReRAM cell configured to exhibit multiple resistance states for storing multiple data bits; a static random-access memory (SRAM) cell configured for temporally retaining multiple data bits loaded from the array of ReRAM cells for performing a CIM operation; a differentially sensing circuit coupled between the array of ReRAM cells and the SRAM cell, and configured for differentially sensing a most significant bit (MSB) and a least significant bit (LSB) of the data when the data is loaded from a ReRAM cell to the SRAM cell.

### CROSS-REFERENCE TO RELATED APPLICATIONS

The present application claims priority from the United States Provisional Ser. No. 63/711,711 filed 25 Oct. 2024, and the disclosure of which is incorporated herein by reference in its entirety.

### FIELD OF THE INVENTION

The present invention generally relates to computing-in-memory (CIM) technologies for artificial intelligence computing, and specifically relates to a hybrid CIM device based on a resistive random-access memory (ReRAM) array and a static random-access memory (SRAM) cell, and a method for sensing multi-level data bit from a ReRAM cell in the same.

### BACKGROUND OF THE INVENTION

Static random-access memory (SRAM) CIM is a promising approach to implement efficient accelerator architecture as it enables accurate, energy-efficient AI computing, supporting both analog and digital computation. However, the large footprint of SRAM makes it impractical to store all weights in CIM macros. The system-level efficiency of SRAM-CIM-based accelerators is compromised by the high energy consumption and long latency associated with the movement of weight data from off-chip memory to on-chip buffer and CIM macros. On the other hand, non-volatile memory such as resistive RAM (ReRAM) provides dense on-chip storage, especially with multi-level cells (MLC), but ReRAM-CIM may introduce inaccuracies due to device variation and only supports analog computation.

To leverage the strengths of both SRAM and non-volatile memory, fine-grained hybrid integration at the cell level can be employed. One proposed design is a high-density non-volatile SRAM (nvSRAM) cell that integrates multiple single-level (SL) ReRAM resistors into an SRAM cell for local storage. Data stored in each non-volatile resistor can be retrieved into its associated SRAM cell for computation, resulting in high energy and area efficiency. However, this design utilizes a current-based ReRAM data sensing scheme with a small signal margin, relying on the limited gain of the SRAM to amplify the data signal. As the number of embedded resistors increases, the correctness of data retrieval diminishes rapidly, posing a challenge to achieving accurate computation and scalable accelerator design.

To address this challenge, a triple-level (TL)-nvSRAM design is proposed to incorporate a resistive selector device alongside the ReRAM resistors within the SRAM. This configuration switches off the unselected ReRAM cells, preventing interference with data retrieval. As a result, memory density is improved by enabling triple-level ReRAM data readout. However, this design still relies on SRAM to amplify the data signal, and the use of selector resistors affects the signal margin of ReRAM readout. Consequently, the accuracy of CNN computations is impacted by inaccuracies in ReRAM data retrieval. Furthermore, supporting ternary CIM computation doubles the number of SRAM multiplication branches, leading to reduced energy and area efficiency. Additionally, this approach incurs overhead for digital CIM, as implementing ternary addition and multiplication digitally is more costly than their binary counterparts.

### SUMMARY OF THE INVENTION

To address above said issues, the present invention provides a hybrid memory array for computing-in-memory applications. It consists of a 1-transistor-1-resistor (1T1R) resistive RAM (ReRAM) crossbar array configured to store multi-level cells (MLCs) that encode 2-bit weight data. The hybrid memory array is complemented by a reference resistance column and a specialized static random-access memory (SRAM) cell. The SRAM features a 6-transistor design, enhanced with additional components for efficient data handling.

In accordance with one aspect of the present invention, a hybrid computing-in-memory (CIM) device is provided and comprising: an array of resistive random-access memory (ReRAM) cells, each ReRAM cell configured to exhibit multiple resistance states for storing multiple data bits; a static random-access memory (SRAM) cell configured for temporally retaining a data bit loaded from the array of ReRAM cells for performing a CIM operation; a differentially sensing circuit coupled between the array of ReRAM cells and the SRAM cell, and configured for differentially sensing a most significant bit (MSB) or a least significant bit (LSB) of the data when the data is loaded from a ReRAM cell to the SRAM cell.

In accordance with another aspect of the present invention, a method for sensing multi-level data bit from a target ReRAM cell in the hybrid computing-in-memory (CIM) device is provided. The method comprises: applying enabling pulses to open local transmission gates in the SRAM cell to transfer the last sensed data bit from the SRAM cell to the reference selection transistors (nodes M and MB); selecting a column containing a target ReRAM cell through a corresponding selection line; asserting a latch signal to low to disable the SRAM cell; precharing a pair of bit lines to a safe voltage; enabling the target ReRAM cell to discharge the bit lines by applying a pulse to a corresponding word line; activating and controlling the differentially sensing circuit to sense the data bit stored in the target ReRAM cell through a least significant bit (LSB) word line and a most significant bit (MSB) word line; and asserting the latch signal to high to enable the SRAM cell to capture the sensed data bit. The differentially sensing circuit includes: a least significant bit (LSB) sensing branch configured for reading least significant bit of data stored in the target ReRAM cell and being enabled or disabled through the LSB word line; and a most significant bit (MSB) sensing branch configured for reading most significant bit of data stored in the target ReRAM cell and being enabled or disabled through the MSB word line.

The present invention allows for effective transfer of weight data from the ReRAM to the SRAM during operation, enabling computation of output values on basis of input data and stored weights, while ensuring resilience against data variations. By integrating ReRAM storage with SRAM-based sensing and computation circuitry, this design offers a highly efficient platform for CIM systems. It reduces data transfer latency, enhances processing speed, and supports scalable multi-bit weight representation, which is particularly advantageous for machine learning and other data-intensive applications.

### BRIEF DESCRIPTION OF THE DRAWINGS

Embodiments of the invention are described in more details hereinafter with reference to the drawings, in which:

FIG. 1 shows a simplified schematic diagram of a hybrid computing-in-memory (CIM) device in accordance with one embodiment of the present invention;

FIG. 2 shows a schematic diagram of a ReRAM crossbar array in accordance with one embodiment of the present invention;

FIG. 3 shows a schematic diagram of an exemplary ReRAM cell;

FIG. 4 shows a schematic diagram of a SRAM cell in accordance with one embodiment of the present invention;

FIG. 5 shows a schematic diagram of an exemplary bistable latch in the SRAM cell;

FIG. 6 shows a schematic diagram of a differential sensing circuit in accordance with one embodiment of the present invention;

FIG. 7 shows a schematic diagram of a differential sensing circuit in accordance with another embodiment of the present invention;

FIG. 8 shows a schematic diagram of a precharging circuit in accordance with another embodiment of the present invention;

FIG. 9 shows a schematic diagram of a global switching circuit in accordance with one embodiment of the present invention;

FIG. 10A shows a schematic diagram of an analog CIM circuit in accordance with one embodiment of the present invention; and FIG. 10B shows a schematic diagram of a digital CIM circuit in accordance with another embodiment of the present invention;

FIGS. 11A to 11D illustrate connections of the hybrid CIM device during the four phases of the ReRAM reading mechanism;

FIG. 12 shows the timing diagrams of the hybrid CIM device during the four phases of FIGS. 11A to 11D; and

FIG. 13 shows a schematic of connections of the hybrid CIM device during ReRAM writing.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

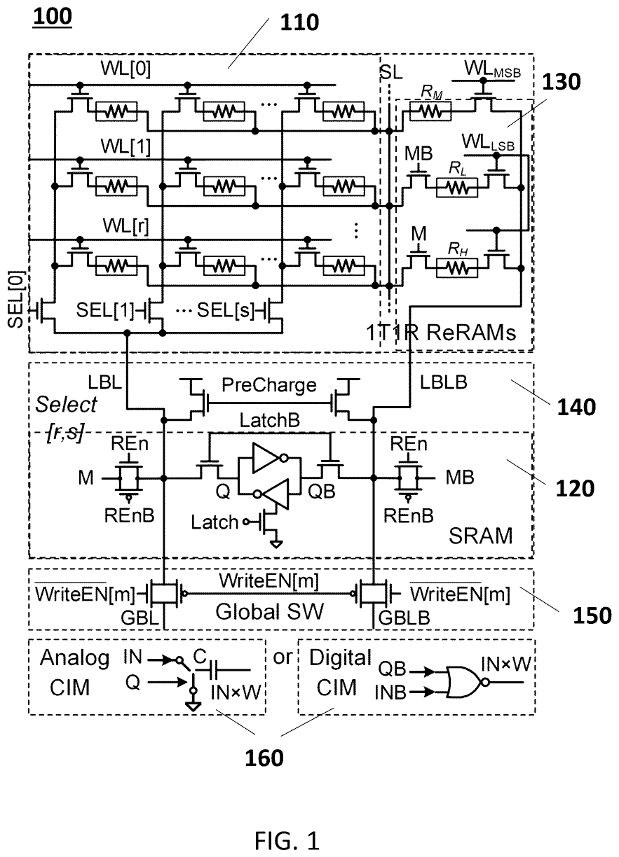

FIG. 1 shows a simplified circuit diagram of a hybrid computing-in-memory (CIM) device 100 in accordance with one embodiment of the present invention. As shown, the hybrid CIM device 100 comprises a crossbar array of resistive random-access memory (ReRAM) cells 110, each ReRAM cell configured to exhibit multiple resistance states for storing multiple data bits; a static random-access memory (SRAM) cell 120 configured for temporally retaining multiple data bits loaded from the array of ReRAM cells for performing a CIM operation; and a differentially sensing circuit 130 coupled between the array of ReRAM cells and the SRAM cell, and configured for differentially sensing a most significant bit (MSB) and a least significant bit (LSB) of the data when the data is loaded from a ReRAM cell to the SRAM cell.

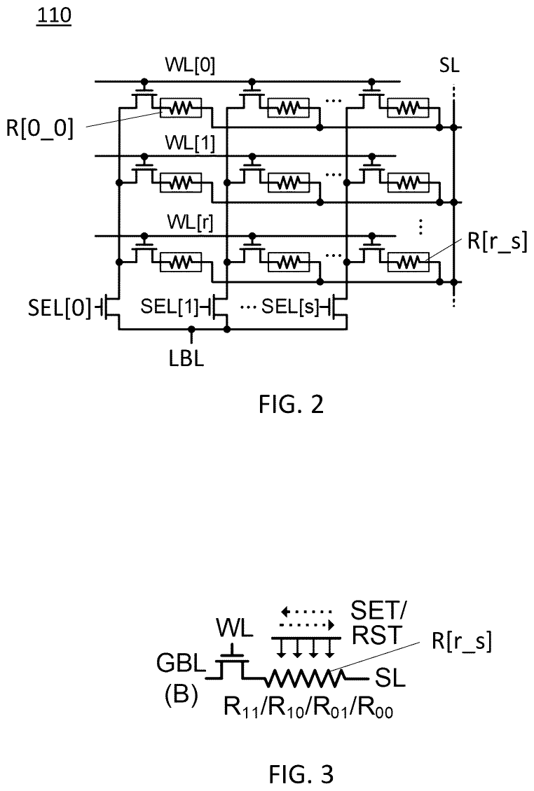

Referring to FIG. 2, the ReRAM cell array 110 includes: a plurality of word lines, WL[r]; a plurality of selection lines, SEL[s], intersecting the word lines to form a crossbar structure; and a plurality of resistive memory elements, R[r_s], disposed at intersections of the word lines and the selection lines, each resistive memory element comprising a first electrode electrically connected to a corresponding word line and a second electrode electrically connected to a corresponding selection line.

Referring to FIG. 3, each ReRAM cell (i.e. resistive memory element, R[r_s]) is configurable to store 2-bit weight data by adopting one of four distinct resistance states: R_11, R_10, R_01, and R_00. This fine-grained representation enables compact and high-density weight storage, which is essential for efficient implementation of CIM operations.

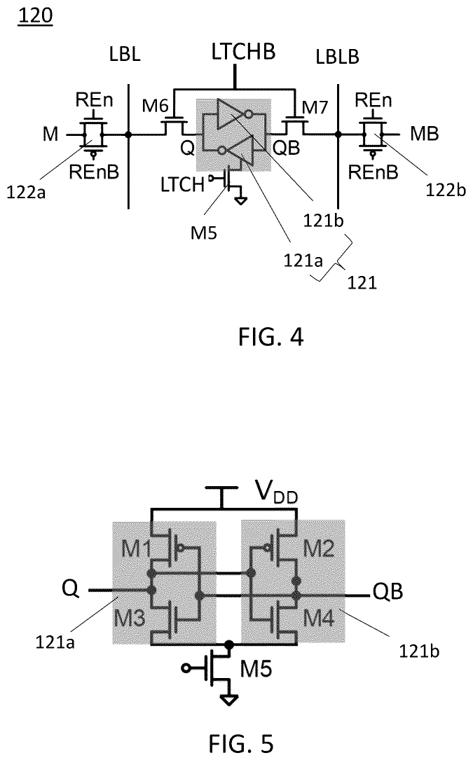

Referring to FIG. 4, the SRAM cell 120 includes: a bistable latch 121 connected between a first latch node (Q) and a second latch node (QB); a latch enabling transistor (M5) connected between the bistable latch and a ground and having a gate controlled by a latch control signal LTCH; and a pair of first and second local bit lines (LBL, LBLB) coupled to the first and second latch nodes (Q, QB) through a first access transistor (M6) and a second access transistor (M7), respectively.

The bistable latch 121 may include a pair of first and second inverters 121a, 121b cross-coupled to the first latch node Q and second latch node QB. Referring to FIG. 5, the first inverter 121a may comprise: a first p-type transistor (M1) having a source connected to a voltage supply (V_{DD}), a drain connected to the first latch node (Q) and a gate connected to the second latch node (QB); and a first n-type transistor (M3) having a source connected to the first latch node (Q), a drain connected to the latch enabling transistor (M5) and a gate connected to the second latch node (QB). The second inverter 121b may comprise: a second p-type transistor (M2) having a source connected to the voltage supply (V_{DD}), a drain connected to the second latch node (QB) and a gate connected to the first latch node (Q); and a second n-type transistor (M4) having a source connected to the second latch node (QB), a drain connected to the latch enabling transistor (M5) and a gate connected to the first latch node (Q).

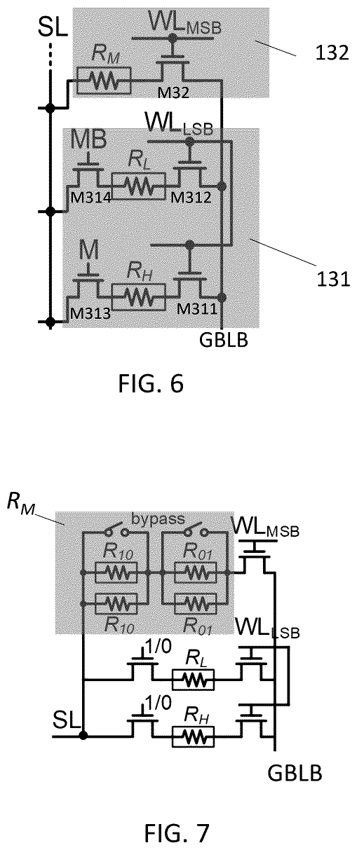

The differentially sensing circuit 130 is configured to ensure accurate sensing of stored data and enable robust distinction among the multiple resistance levels of the ReRAM cells. Referring to FIG. 6, the differentially sensing circuit 130 includes: a least significant bit (LSB) sensing branch 131 and a most significant bit (MSB) sensing branch 132.

The LSB sensing branch 131 comprises: a high reference resistor R_{H}; a low reference resistor R_{L}; a first LSB enabling transistor M311, a second LSB enabling transistor M312, a high reference selection transistor M313 and a low reference selection transistor M314. The first LSB enabling transistor M311 is connected between the high reference resistor R_{H} and the second global bit line GBLB, and has a gate connected to the LSB word line (WL_{LSB}). The second LSB enabling transistor M312 is connected between the low reference resistor R_{L} and the second global bit line GBLB, and has a gate connected to a LSB word line (WL_{LSB}). The high reference selection transistor M313 is connected between the high reference resistor R_{H} and the reference selection line SL, and has a gate connected to a high reference selection node M. The low reference selection transistor M314 is connected between the low reference resistor R_{L} and the reference selection line SL, and has a gate connected to a low reference selection node MB.

The MSB sensing branch comprises: a medium reference resistor R_{M}; and a medium reference enabling transistor connected between the medium reference resistor R_{M} and the second global bit line GBLB, and having a gate connected to the MSB word line (WL_{MSB});

In some embodiments, the medium reference resistor R_{M} is formed of a series-parallel combination of reference resistive cells. For example, as shown in FIG. 7, the medium reference resistor R_{M} may be formed by pairing two parallel connected first reference resistive cells (R_10) in series with two parallel connected second reference resistive cells (R_01) . This approach enhances the separation between adjacent resistance states, thereby improving readout accuracy while simultaneously reducing the overhead associated with programming precise reference levels. By comparing the sensed resistance to known reference values, the system can reliably decode the stored 2-bit weight data.

Referring back to FIGS. 1 and 4, the SRAM cell 120 further includes a pair of first and second local transmission gates 122a, 122b. The first local transmission gate 122a is connected between the first local bit line LBL and the high reference selection node M connecting to the gate of the high reference selection transistor M313, having a first control terminal connected to a first reading enabling signal (REn) and a second control terminal connected to a second reading enabling signal (REnB). The second local transmission gate 122b is connected between the second local bit line LBLB and the low reference selection node MB, having a first control terminal connected to the reading enabling signal (REn) and a second control terminal connected to the second reading enabling signal (REnB).

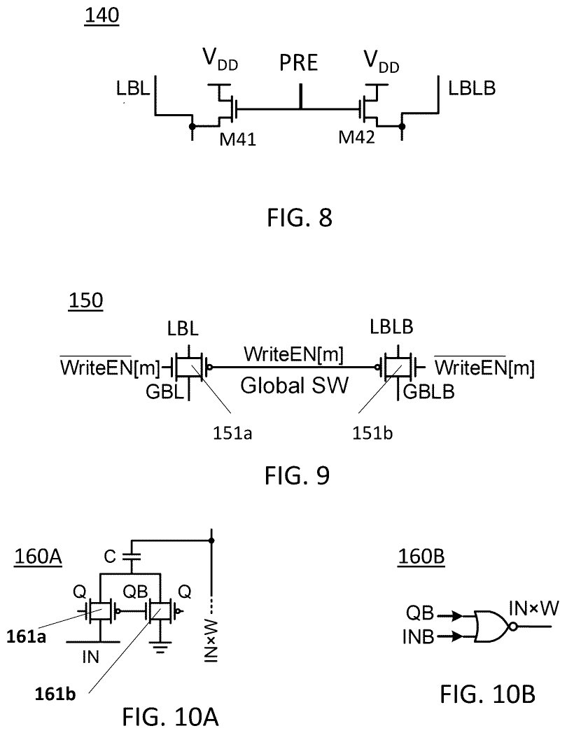

Referring to FIGS. 1 and 8, the hybrid CIM device 100 may further include a pre-charging circuit 140 for pre-charging the first and second nodes of the bistable latch. The pre-charging circuit 140 may include: a first precharge transistor M41 having a drain connected to a DC voltage supply V_{DD}, a source connected to the first local bit line LBL, and a gate connected to a precharge control signal PRE; and a second precharge transistor M42 having a drain connected to the DC voltage supply V_{DD}, a source connected to the second local bit line LBLB, and a gate connected to the precharge control signal PRE.

Referring to FIGS. 1 and 9, the hybrid CIM device 100 may further include a global switching circuit 150 coupled to the SRAM cell 120 for writing operation. The global switching circuit 150 may include: a first global transmission gate 151a connected between the first global bit line GBL and the first local bit line LBL, having a first control terminal connected to a write enabling signal (WriteEN) and a second control terminal connected to a complementary write enabling signal (W̅r̅i̅t̅e̅E̅N̅); and a second global transmission gate 151b connected between the second global bit line GBLB and the second local bit line LBLB, having a first control terminal connected to a write enabling signal (WriteEN) and a second control terminal connected to a complementary write enabling signal (W̅r̅i̅t̅e̅E̅N̅).

Referring back to FIG. 1, the hybrid CIM device 100 may further include a CIM circuit 160 configured for performing a multiply-accumulate (MAC) operation on an input data and the weight data stored in the hybrid CIM device. The CIM circuit has a first input connected to the second node QB of the SRAM cell to receive weight data and a second input connected to an input data line to receive input data IN and generate an output representing a MAC product INxW of the input data and weight data.

In one embodiment, the CIM circuit 160 may be an analog CIM circuit 160A as shown in FIG. 10A, including: a capacitor C and a pair of transmission gates 161a, 161b. Transmission gate 161a is connected between a first end of the capacitor C and an input data line, having a positive control terminal connected to the first latch node (Q) of the SRAM cell and a negative control terminal connected to the second latch node (QB) of the SRAM cell. Transmission gate 161b is connected between the first end of the capacitor C and a ground, having a negative control terminal connected to the first latch node (Q) of the SRAM cell and a positive control terminal connected to the second latch node (QB) of the SRAM cell. The second end of the capacitor acts as the output representing the MAC product INxW of the input data and weight data. In another embodiment, the CIM circuit 160 may be digital CIM circuit 160B as shown in FIG. 10B, including a NAND gate having a first input connected to the second node of the SRAM cell, a second input connected to an input data line, and an output representing the MAC product INxW of the input data and weight data.

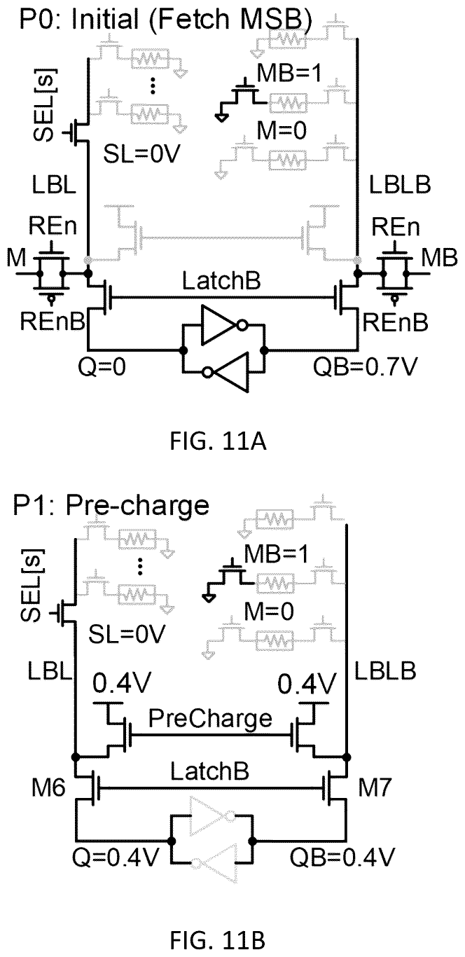

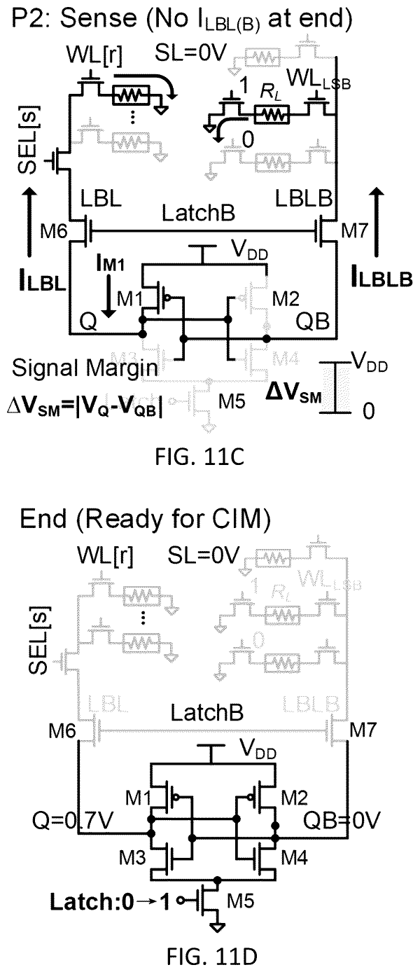

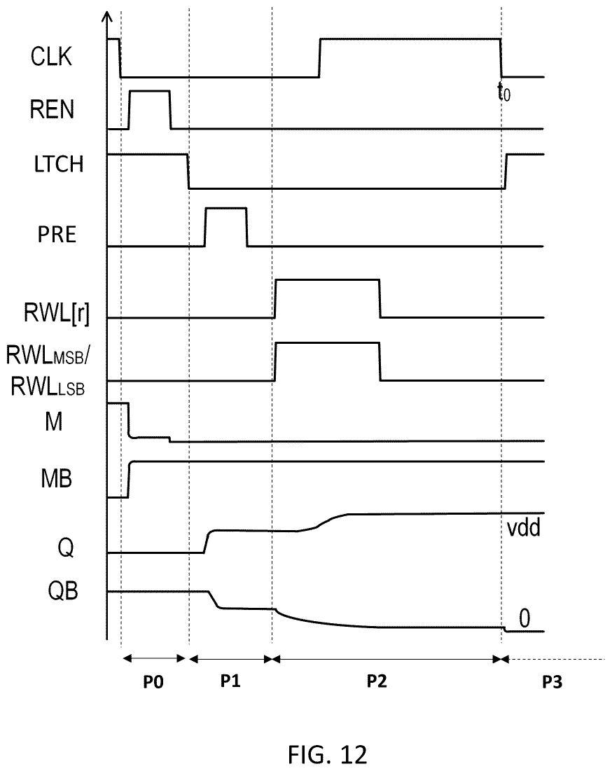

The ReRAM reading mechanism integrates a four-phase sensing scheme designed to efficiently transfer 2-bit weight data stored in local ReRAM crossbars into adjacent SRAM cells. This transfer mechanism supports both Most Significant Bit (MSB) and Least Significant Bit (LSB) sensing operations, enabling accurate in-memory computation with minimized disturbance and power overhead. FIGS. 11A to 11D show schematic of the four phases, namely, initial phase P0, latch disable phase P1, sensing phase P2 and latch enable phase P3, of the ReRAM reading mechanism. FIG. 12 shows the corresponding timing diagrams.

In the initial phase P0, triggered on the falling edge of the system clock (CLK), the enable pulses (REn and REnB) activate the pair of local transmission gates in the SRAM cell. The last sensed data bit stored in the SRAM cell is transferred to reference selection transistors (nodes M and MB). Concurrently, the SEL[s] signal is asserted to select the specific column in the ReRAM array that contains the target cell for the current read operation. For sensing a 2-bit data from the ReRAM cell, after sensing Most Significant Bit and finishing the computing operations, the bit value will be transferred to the gate node of the reference selection transistors (nodes M and MB) at the beginning of sensing operation, acting as selection signal to sense LSB. The sensing operation for the MSB and LSB are similar except that the different word lines, WL_{MSB} and WL_{LSB} are used respectively. The nodes M and MB and reference resistors will do nothing when sensing Most Significant Bit from ReRAM since only WL_{MSB} is activated. So the initial phase only applicable for Most Significant Bit sensing. For Least Significant Bit sensing, the initial phase is a dummy phase.

During the latch phase P1, the latch signal (LTCH) transitions low, temporarily disabling the SRAM cell to prevent unintended interference during sensing. Simultaneously, a precharge signal (PRE) pulse is applied to the local bit lines (LBL and LBLB), bringing them to a pre-determined safe voltage level (V_pre=400 mV). This precharge ensures minimal read-disturb to the ReRAM cell by controlling the voltage differential prior to discharge.

The core read operation occurs in the sensing phase P2, where a word line signal (RWL[r]) pulse is used to activate the word line of the selected ReRAM row, allowing the targeted cell to begin discharging the LBL. At the same time, appropriate reference resistors are connected to LBLB through either the WL_MSB or WL_LSB lines through the signals RWL_{MSB} or RWL_{LSB}, depending on whether the MSB or LSB is being read.

For MSB readings, WL_MSB couples a medium reference resistor (R_M) to LBLB. For LSB readings, WL_LSB connects a high and low resistor (R_H and R_L) to LBLB. The data at nodes M and MB determines the reference resistor for LSB reading.

Discharging speeds may vary, allowing the cross-coupled PMOS transistors of the 6-T SRAM cell to pull nodes Q and QB to opposite values, achieving a full-rail output.

Finally, in the latch enable phase P3, the latch signal (LTCH) transitions high in the subsequent clock cycle, thereby enabling the SRAM to capture the full-rail data for computation since Q and QB are already stable and driven to full rail levels (V_{DD} and 0).

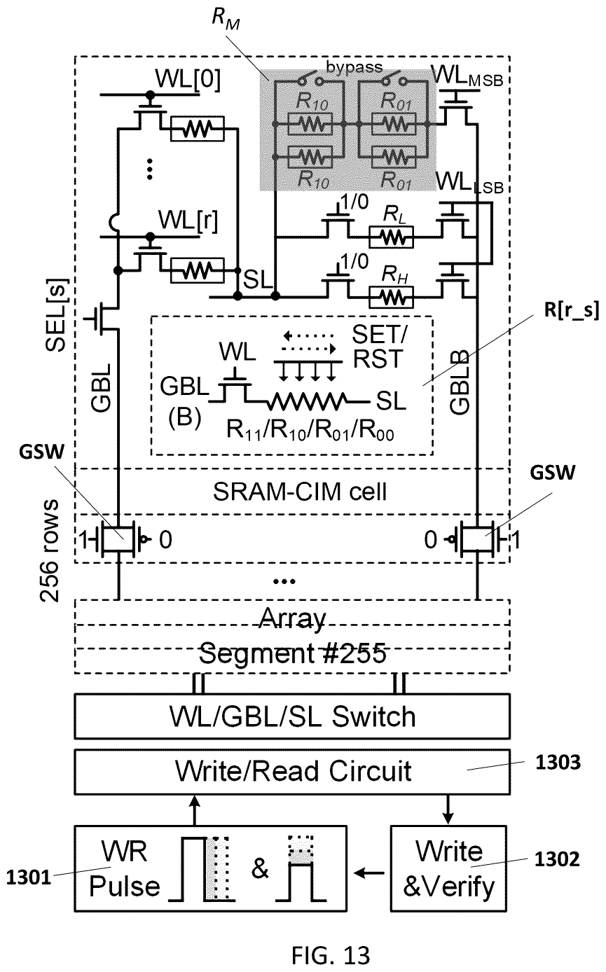

FIG. 13 shows a schematic of ReRAM writing connections of the hybrid CIM device. The resistance state of the ReRAM cell is programmable through applying voltage pulses thereon. As shown in FIG. 13, when the global switch GSW is opened, writing (WR) pulses 1301 can be applied to the target ReRAM cell R[r_s] through the global bit lines GBL and GBLB, and reference selection line SL. Write-and-verify circuit 1302 and write circuits 1303 will program the ReRAM cell to the target resistance value. To facilitate computation, selected ReRAM cells can be dynamically loaded into nearby SRAM structures, allowing localized processing with minimal data movement. Access to specific ReRAM cells is controlled through a selection mechanism comprising the word lines (WLs) and selection lines (SELs). The coordinated activation of these lines permits precise addressing and retrieval of data from individual cells. This selective accessibility ensures that only the intended memory cells are engaged during read or compute phases, which is critical for power-efficient and collision-free operation within the dense crossbar array.

The functional units and modules of the hybrid CIM device in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance to the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

While the present disclosure has been described and illustrated with reference to specific embodiments thereof, these descriptions and illustrations are not limiting. The illustrations may not necessarily be drawn to scale. There may be distinctions between the illustrations in the present disclosure and the actual apparatus due to manufacturing processes and tolerances. There may be other embodiments of the present disclosure which are not specifically illustrated. Modifications may be made to adapt a particular situation, material, composition of matter, method, or process to the objective and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A hybrid computing-in-memory (CIM) device, comprising:
an array of resistive random-access memory (ReRAM) cells, each ReRAM cell configured to exhibit multiple resistance states for storing multiple data bits;
a static random-access memory (SRAM) cell configured for temporally retaining one or more data bits loaded from the array of ReRAM cells for performing a CIM operation;
a differentially sensing circuit coupled between the array of ReRAM cells and the SRAM cell, and configured for differentially sensing a most significant bit (MSB) and a least significant bit (LSB) of the data when the data is loaded from a ReRAM cell to the SRAM cell.

2. The hybrid computing-in-memory (CIM) device of claim 1, wherein the ReRAM cell array includes:
a plurality of word lines (WL[r]);
a plurality of selection lines (SEL[s]) intersecting the word lines to form a crossbar structure; and
a plurality of resistive memory elements (R[r_s]) disposed at intersections of the word lines and the selection lines, each resistive memory element comprising a first electrode electrically connected to a corresponding word line and a second electrode electrically connected to a corresponding selection line.

3. The hybrid computing-in-memory (CIM) device of claim 1, wherein each ReRAM cell is configurable to have four resistance states for storing two data bits.

4. The hybrid computing-in-memory (CIM) device of claim 1, wherein the static random-access memory (SRAM) cell includes:
a bistable latch including a pair of first and second inverters cross-coupled between a first latch node (Q) and a second latch node (QB);
a latch enabling transistor (M5) connected between the bistable latch and a ground and having a gate controlled by a latch control signal; and
a pair of first and second local bit lines (LBL, LBLB) coupled to the first and second latch nodes (Q, QB) through a first access transistor (M6) and a second access transistor (M7), respectively.

5. The hybrid computing-in-memory (CIM) device of claim 4, wherein the first inverter comprises:
a first p-type transistor (M1) having a source connected to a voltage supply (VDD), a drain connected to the first latch node (Q) and a gate connected to the second latch node (QB); and
a first n-type transistor (M3) having a source connected to the first latch node (Q), a drain connected to the latch enabling transistor (M5) and a gate connected to the second latch node (QB); and
the second inverter comprises:
a second p-type transistor (M2) having a source connected to the voltage supply (VDD), a drain connected to the second latch node (QB) and a gate connected to the first latch node (Q); and
a second n-type transistor (M4) having a source connected to the second latch node (QB), a drain connected to the latch enabling transistor (M5) and a gate connected to the first latch node (Q).

6. The hybrid computing-in-memory (CIM) device of claim 5, wherein the static random-access memory (SRAM) cell further includes:
a pre-charging circuit for precharing the first and second nodes of the bistable latch, the pre-charging circuit comprising:
a first precharge transistor having a drain connected to a DC voltage supply, a source connected to the first local bit line, and a gate connected to a precharge control signal; and
a second precharge transistor having a drain connected to the DC voltage supply, a source connected to the second local bit line, and a gate connected to the precharge control signal.

7. The hybrid computing-in-memory (CIM) device of claim 6, wherein the differentially sensing circuit includes:
a least significant bit (LSB) sensing branch configured for reading least significant bit of data stored in the SRAM cell; and
a most significant bit (MSB) sensing branch configured for reading most significant bit of data stored in the SRAM cell.

8. The hybrid computing-in-memory (CIM) device of claim 7, wherein the least significant bit (LSB) sensing branch comprises:
a high reference resistor R_{H};
a low reference resistor R_{L};
a first LSB enabling transistor connected between the high reference resistor R_{H} and the second global bit line GBLB, and having a gate connected to the LSB word line (WL_{LSB});
a second LSB enabling transistor connected between the low reference resistor R_{L} and the second global bit line GBLB, and having a gate connected to a LSB word line (WL_{LSB});
a high reference selection transistor connected between the high reference resistor R_{H} and a reference selection line SL, and having a gate connected to a high reference selection node M; and
a low reference selection transistor connected between the low reference resistor R_{L} and the reference selection line SL, and having a gate connected to a low reference selection node MB.

9. The hybrid computing-in-memory (CIM) device of claim 7, wherein the most significant bit (MSB) sensing branch comprises:
a medium reference resistor R_{M} coupled to the reference selection line SL; and
a medium reference enabling transistor connected between the medium reference resistor R_{M} and the second global bit line GBLB, and having a gate connected to the MSB word line (WL_{MSB}).

10. The hybrid computing-in-memory (CIM) device of claim 9, wherein the medium reference resistor R_{M} is formed of a series-parallel combination of reference resistive cells.

11. The hybrid computing-in-memory (CIM) device of claim 7, wherein the static random-access memory (SRAM) cell further includes:
a first local transmission gate connected between the first local bit line and a gate of the selection transistor (M) for the high reference resistor R_{H}, having a first control terminal connected to a first reading enabling signal (REn) and a second control terminal connected to a second reading enabling signal (REnB); and
a second local transmission gate connected between the second local bit line and a gate of the selection transistor (MB) for the low reference resistor R_{L}, having a first control terminal connected to a reading enabling signal (REn) and a second control terminal connected to a second reading enabling signal (REnB).

12. The hybrid computing-in-memory (CIM) device of claim 1, further comprising a global switching circuit coupled to the SRAM cell for writing operation, the global switching circuit includes:
a first global transmission gate connected between the first global bit line and the first local bit line, having a first control terminal connected to a write enabling signal (WriteEN) and a second control terminal connected to a complementary write enabling signal (W̅r̅i̅t̅e̅E̅N̅); and
a second global transmission gate connected between the second global bit line and the second local bit line, having a first control terminal connected to a write enabling signal (WriteEN) and a second control terminal connected to a complementary write enabling signal (W̅r̅i̅t̅e̅E̅N̅).

13. The hybrid computing-in-memory (CIM) device of claim 1, further comprising a digital CIM circuit including a NAND gate having a first input connected to the second node of the SRAM cell, a second input connected to an input signal line.

14. The hybrid computing-in-memory (CIM) device of claim 1, further comprising a an analogue CIM circuit include a capacitor and a switch.

15. A method for sensing multi-level data bit from a target ReRAM cell in the hybrid computing-in-memory (CIM) device of claim 1, comprising:
applying enabling pulses to open local transmission gates in the SRAM cell to transfer the last sensed data bit from the SRAM cell to the reference selection transistors (nodes M and MB);
selecting a column containing a target ReRAM cell through a corresponding selection line;
asserting a latch signal to low to disable the SRAM cell;
precharing a pair of bit lines to a safe voltage;
enabling the target ReRAM cell to discharge the bit lines by applying a pulse to a corresponding word line;
activating and controlling the differentially sensing circuit to sense the data bit stored in the target ReRAM cell through a least significant bit (LSB) word line and a most significant bit (MSB) word line; and
asserting the latch signal to high to enable the SRAM cell to capture the sensed data bit; and
wherein the differentially sensing circuit includes:
a least significant bit (LSB) sensing branch configured for reading least significant bit of data stored in the SRAM cell and being enabled or disabled through the LSB word line; and
a most significant bit (MSB) sensing branch configured for reading most significant bit of data stored in the SRAM cell and being enabled or disabled through the MSB word line.

16. The method according to claim 15, wherein the most significant bit (MSB) sensing branch comprises:
a medium reference resistor R_{M} coupled to the reference selection line SL; and
a medium reference enabling transistor connected between the medium reference resistor R_{M} and the second global bit line GBLB, and having a gate connected to the MSB word line (WL_{MSB}).

17. The method according to claim 16, wherein the medium reference resistor is formed of a series-parallel combination of reference resistive cells.

18. The method according to claim 15, wherein the least significant bit (LSB) sensing branch comprises:
a high reference resistor R_{H};
a low reference resistor R_{L};
a first LSB enabling transistor connected between the high reference resistor R_{H} and the second global bit line GBLB, and having a gate connected to the LSB word line (WL_{LSB});
a second LSB enabling transistor connected between the low reference resistor R_{L} and the second global bit line GBLB, and having a gate connected to a LSB word line (WL_{LSB});
a high reference selection transistor connected between the high reference resistor R_{H} and a reference selection line SL, and having a gate connected to a high reference selection node M; and
a low reference selection transistor connected between the low reference resistor R_{L} and the reference selection line SL, and having a gate connected to a low reference selection node MB; and
the differentially sensing circuit is further controlled to select the high or low reference resistors to sense the data bit based on data at the high reference selection node M and the low reference selection node MB.
